(19) United States
(12) Patent Application Publication
(10) Pub. No.: US 2016/0284872 A1
(43) Pub. Date: Sep. 29, 2016

(54) SCHOTTKY DIODE

(71) Applicant: ELECTRONICS AND TELECOMMUNICATIONS RESEARCH INSTITUTE, Daejeon (KR)

(72) Inventors: Kun Sik PARK, Daejeon (KR); Jong II WON, Sejong (KR); Doo Hyung CHO, Daejeon (KR)

(21) Appl. No.: 15/080,338

(22) Filed: Mar. 24, 2016

(30) Foreign Application Priority Data
Mar. 26, 2015 (KR) 10-2015-0042666
Feb. 17, 2016 (KR) 10-2016-0018592

(51) Int. Cl. H01L 29/872; H01L 29/16; H01L 29/06

(52) U.S. Cl. CPC H01L 29/872; H01L 29/0615; H01L 29/1608

(57) ABSTRACT

Provided is a Schottky diode including a substrate, a drift layer on the substrate, the drift layer comprising an active region and a periphery positioned at an edge of the active region, a junction termination layer on a boundary between the active region and the periphery, a first metal layer configured to cover a part of the active region and a part of the junction termination layer, and a second metal layer configured to cover the first metal layer and the active region, wherein the first metal layer and the second metal layer contact the drift layer to provide a Schottky junction, and the first metal layer has a higher Schottky barrier height than the second metal layer.

### CROSS-REFERENCE TO RELATED APPLICATIONS

This U.S. non-provisional patent application claims priority under 35 U.S.C. §119 of Korean Patent Application Nos. 10-2015-0042666, filed on Mar. 26, 2015, and 10-2016-0018592, filed on Feb. 17, 2016, the entire contents of which are hereby incorporated by reference.

### BACKGROUND

The present disclosure herein relates to a diode, and more particularly, to a Schottky diode.

A Schottky diode, which is a semiconductor device formed of a metal contacting a semiconductor layer, provides a Schottky barrier and uses a metal-semiconductor junction generated between a metal layer and a doped semiconductor layer. In general, the Schottky diode operates like a typical p-n diode, which easily passes a current in a forward bias and cuts off a current in a reverse bias. A Schottky barrier provided in a metal-semiconductor junction forms a rectifying junction unit having an improved diode switching capability in comparison to a p-n diode. Firstly, since the Schottky barrier has a lower barrier height related to a lower forward voltage drop and operates due to movement of multiple carriers, there is not a rejoining operation of minority carriers having a low speed. Accordingly, the Schottky diode has a lower turn-on voltage and a more rapid switching speed in comparison to the p-n diode. The Schottky diode is ideal to applications in which a switching loss is a major energy consumption source like a switch-mode power supply (SMPS). However, the current Schottky diodes show relatively low reverse-bias voltage ratings and high reverse-bias leakage currents.

### SUMMARY

The present disclosure provides a Schottky diode of which reverse blocking characteristics are improved.

Issues to be addressed in the present disclosure are not limited to those described above and other issues unmentioned above will be clearly understood by those skilled in the art from the following description.

An embodiment of the inventive concept provides a Schottky diode including: a substrate; a drift layer on the substrate, the drift layer comprising an active region and a periphery positioned at an edge of the active region; a junction termination layer on a boundary between the active region and the periphery; a first metal layer configured to cover a part of the active region and a part of the junction termination layer; and a second metal layer configured to cover the first metal layer and the active region. The first metal layer and the second metal layer contact the drift layer to provide a Schottky junction. The first metal layer has a higher Schottky barrier height than the second metal layer.

In an embodiment, the substrate, the drift layer and the junction termination layer may include silicon carbide SiC.

In an embodiment, the Schottky diode may further include a plurality of conductive layers spaced apart from each other on the active region. The second metal layer may cover the first metal layer, the active region, and the conductive layers.

In an embodiment, the conductive layers may have a conductive type different from that of the drift layer.

In an embodiment, the conductive layers may include a first part and a second part on the first part. The second part may have a higher dopant concentration than the first part.

In an embodiment, the Schottky diode may further include a third metal layer configured to cover the conductive layers and a part of the active region. The second metal layer may cover the first metal layer, the active region, and the third metal layer.

In an embodiment, the third metal layer may include a same material as that of the first metal layer.

In an embodiment, the junction termination layer may have a conductive type different from that of the drift layer.

In an embodiment, the junction termination layer may include a first junction termination layer and a second junction termination layer on the first junction termination layer. The second junction termination layer may have a higher dopant concentration than the first junction termination layer.

In an embodiment of the inventive concept, a Schottky diode includes: a substrate; a drift layer on the substrate, the drift layer comprising an active region comprising trenches extending in a substrate direction and a periphery positioned at an edge of the active region; a junction termination layer on a boundary between the active region and the periphery; a first metal layer configured to cover a part of the active region and a part of the junction termination layer; and a plurality of second metal layers disposed separately from each other and configured to contact a top surface of the drift layer and the first metal layer. The first metal layer and the second metal layer may contact the drift layer to provide a Schottky junction. The first metal layer may have a higher Schottky barrier height than the second metal layer.

In an embodiment, the first metal layer may be coated along surface morphologies of the junction termination layer, the active region, and the second metal layer.

In an embodiment, the Schottky diode may further include conductive layers configured to contact a top surface of the drift layer and the first metal layer. The conductive layers may be disposed between the second metal layers.

In an embodiment, side walls of the trenches may have slopes of about 50 to about 90 degrees with respect to bottom surfaces of the trenches.

In an embodiment, the conductive layers may have a conductive type different from that of the drift layer.

In an embodiment, the conductive layers may include a first part and a second part on the first part. The second part may have a higher dopant concentration than the first part.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view for explaining a Schottky diode according to an embodiment of the inventive concept;

FIGS. 2A to 2D are cross-sectional views for explaining modified examples of a Schottky diode according to embodiments of the inventive concept;

FIG. 3 is a method for manufacturing a Schottky diode according to an embodiment of the inventive concept;

FIGS. 4 to 9 are cross-sectional views for explaining a method of manufacturing a Schottky diode according to embodiments of the inventive concept; and

FIGS. 10 to 12 are cross-sectional views for explaining a Schottky diode according to other embodiments of the inventive concept.

### DETAILED DESCRIPTION

The embodiments of the inventive concept will now be described with reference to the accompanying drawings for sufficiently understating a configuration and effects of the inventive concept. However, the inventive concept is not limited to the following embodiments and may be embodied in different ways, and various modifications may be made thereto. The embodiments are just given to provide complete disclosure of the inventive concept and to provide thorough understanding of the inventive concept to those skilled in the art. It will be understood to those skilled in the art that the inventive concept may be performed in a certain suitable environment. Throughout this specification, like numerals refer to like elements.

The terms and words used in the following description and claims are to describe embodiments but are not limited the inventive concept. As used herein, the singular forms “a,” “an” and “the” are intended to include the plural forms as well, unless the context clearly indicates otherwise. It will be further understood that the terms “comprises” and/or “comprising” used herein specify the presence of stated components, operations and/or elements but do not preclude the presence or addition of one or more other components, operations and/or elements.

When a film (or layer) is referred to as being ‘on’ another film (or layer) or substrate, it can be directly on the other film (or layer) or substrate, or intervening films (or layers) may also be present.

Although the terms first, second, third etc. may be used herein to describe various regions, and films (or layers) etc., the regions and films (or layers) are not to be limited by the terms. The terms may be used herein only to distinguish one region or film (or layer) from another region or film (or layer). Therefore, a layer referred to as a first film in one embodiment can be referred to as a second film in another embodiment. An embodiment described and exemplified herein includes a complementary embodiment thereof. Like reference numerals refer to like elements throughout.

Example embodiments are described herein with reference to cross-sectional views and/or plan views that are schematic illustrations of example embodiments. In the drawings, the thicknesses of layers and regions are exaggerated for clarity. As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features. Thus, the regions illustrated in the figures are schematic in nature and their shapes may be not intended to illustrate the actual shape of a region of a device and are not intended to limit the scope of example embodiments.

Unless otherwise defined, all terms used herein have the same meaning as commonly understood by one of ordinary skill in the art to which this invention pertains.

Hereinafter, the embodiments of the present invention will now be described in detail with reference to the accompanying drawings.

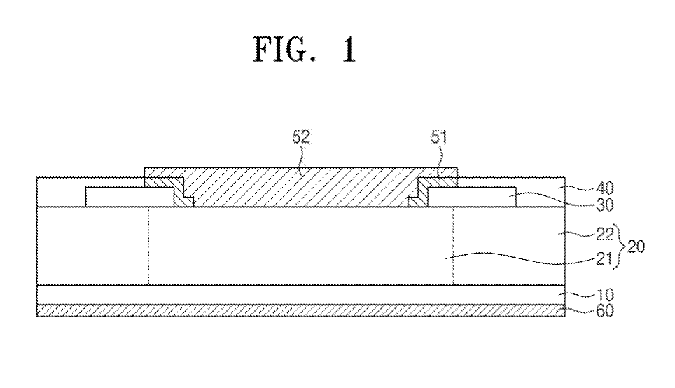

FIG. 1 is a cross-section view for explaining a Schottky diode according to embodiments of the inventive concept. In an embodiment, a vertical silicon carbide (SiC) Schottky diode is exemplified, but the principle of the inventive concept is not limited thereto.

Referring to FIG. 1, a substrate 10 may be provided. The substrate 10 may include silicon carbide (SiC). The substrate 10 may be doped with impurities to have an n-type conductive type. For example, the substrate 10 may be doped with nitrogen (N) or phosphorous (P). At this point, a concentration of the impurity doped to the substrate 10 may be 1-10¹⁸ cm⁻³ to 1-10²⁰ cm⁻³.

A drift layer 20 may be disposed on the substrate 10. The drift layer 20 may include silicon carbide (SiC). The drift layer 20 may be doped with impurities to have an n-type conductive type. For example, the drift layer 20 may be doped with nitrogen (N) or phosphorous (P). A concentration of the impurity doped to the drift layer 20 may be lower than that to the substrate 10. For example, the doping concentration of the drift layer 20 may be 1-10¹³ cm⁻³ to 1-10¹⁷ cm⁻³. The drift layer 20 may include an active region 21 and a periphery 22. In detail, drift layer 20 may include the active region 21 of the central part and the periphery 22 extending from the active region 21 in a lateral direction to surround the active region 21.

A junction termination layer 30 may be disposed on the drift layer 20. In detail, the junction termination layer 30 may be disposed on a boundary between the active region 21 and the periphery 22. At this point, the junction termination layer 30 may cover only a part of the active region 21 and accordingly a part of the top surface of the active region 21 may be exposed. In addition, the junction termination layer 30 may cover a part of or the entirety of the periphery 22. The junction termination layer 30 may include silicon carbide (SiC). The junction termination layer 30 may be doped with impurities to have a p-type conductive type. For example, aluminum (Al) or boron (B) may be doped to the junction termination layer 30. At this point, a concentration of impurity doped to the junction termination layer 30 may be 1-10¹⁵ cm⁻³ to 1-10¹⁹ cm⁻³. The junction termination layer 30 may play a role for reducing an electric field concentrated on a termination end of the active region 21. For example, the junction termination layer 30 may be a junction terminal extension or floating guard ring.

A dielectric layer 40 may be disposed on the junction termination layer 30 and the periphery 22. In detail, the dielectric layer 40 may cover a part of the junction termination layer 30 and the periphery 22. The dielectric layer 40 may include silicon oxide (SiO2). The dielectric layer 40 may be provided to cut off a current toward the periphery 22 to stabilize an element. According to another embodiment, the dielectric layer 40 may not be provided, if necessary.

A first metal layer 51 may be disposed on the active region 21 and the junction termination layer 30. In detail, the first metal layer 41 may be disposed on a boundary between the active region 21 and the junction termination layer 30 to cover parts of the active region 21 and the junction termination layer 30. The first metal layer 51 may contact the active region 21 of the drift layer 20 to form a Schottky junction. The first metal layer 51 may include a metal having a high Schottky barrier height. For example, the first metal layer 51 may include nickel (Ni), gold (Au), or platinum (Pt). The first metal layer 51 partially forms a high barrier height on the boundary between the active region 21 and the junction termination layer 30 to prevent a leakage current caused by an electric field concentrated on the boundary between the active region 21 and the junction termination layer 30.

A second metal layer 52 may be disposed on the active region 21 and the first metal layer 51. The second metal layer 52 may contact the active region 21 of the drift layer 20 to form a Schottky junction. The second metal layer 52 may include a metal having a low Schottky barrier height. For example, the second metal layer 52 may include titanium (Ti), aluminum (Al), niobium (Nb) or tantalum (Ta).

An ohmic contact layer 60 may be disposed on one surface of the substrate 10 facing to the drift layer 20. The ohmic contact layer 60 may contact the substrate 10 to form an ohmic junction and play a role of a cathode of the element.

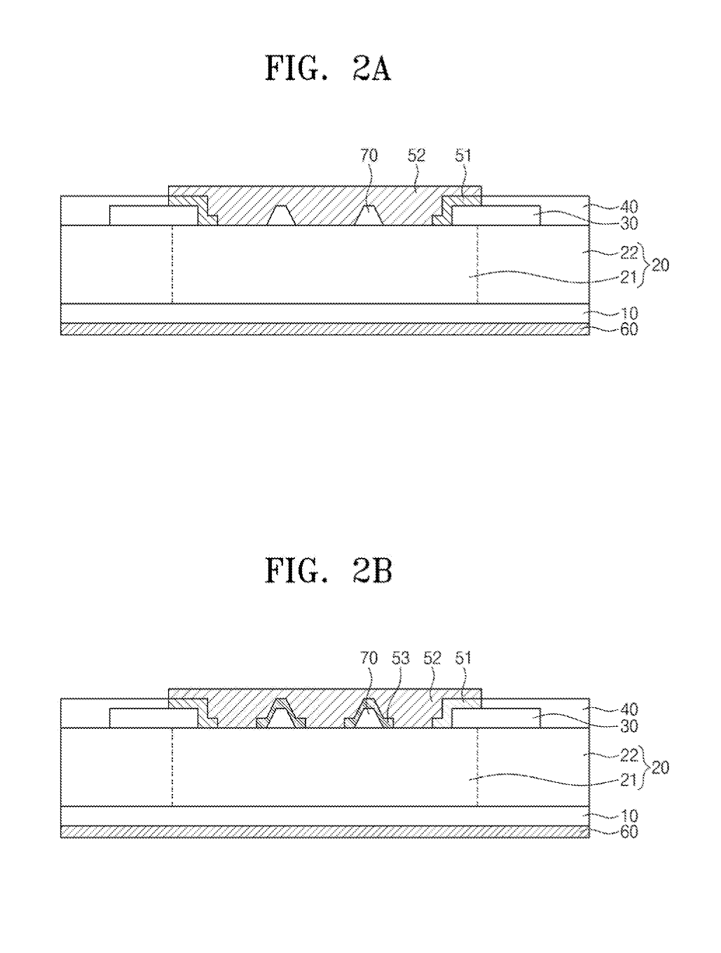

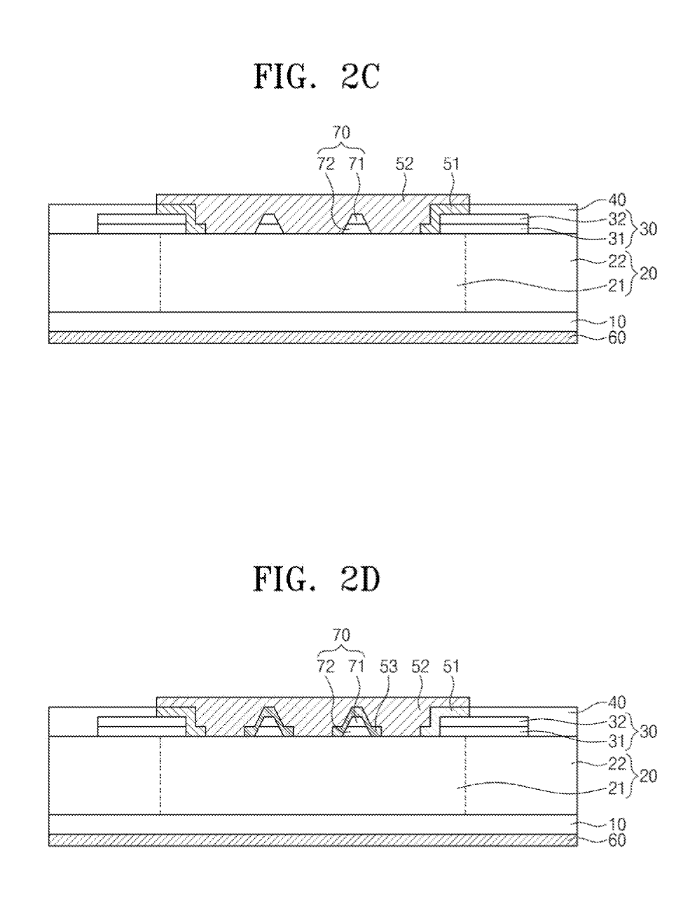

A Schottky diode according to embodiments of the inventive concept may further include a p-n junction for enhancing protection characteristics against a surge current. For convenience of explanation, points different from the embodiment of FIG. 1 will be mainly described and omitted parts may also conform to an embodiment of the inventive concept. FIGS. 2A to 2D are cross-sectional views for explaining modified examples of a Schottky diode according to embodiments of the inventive concept.

Referring to FIG. 2A, at least one conductive layer 70 may be disposed on the active region 21 of the drift layer 20. The conductive layers 70 may have insular shapes. For example, the conductive layers 70 may be disposed on the active region 21 to be planarly spaced apart from each other. The conductive layers 70 may include silicon carbide (SiC). The conductive layers 70 may have conductive types different from the drift layer 20. For example, aluminum (Al) or boron (B) may be doped to the conductive layers 70. At this point, a concentration of impurity doped to the conductive layers 70 may be 1-10¹⁵ cm⁻³ to 1-10¹⁹ cm⁻³. The conductive layers 70 may contact the active region 21 of the drift layer 20 to form a p-n junction. The p-n junction may have a low voltage characteristic at a high current in comparison to the Schottky junction. Accordingly, when a surge current flows through the element, the p-n junction may lower an electric field applied to the element to protect the element. A second metal layer 52 may be disposed on the first metal layer 51, the active region 21, and the conductive layer 70. The second metal layer 52 may contact the active region 21 of the drift layer 20 to form a Schottky junction.

According to another embodiment, the third metal layers may be further disposed on the conductive layers. Referring to FIG. 2B, the third metal layer 53 may cover a part of the active region 21 and the conductive layer 70. The third metal layer 53 may include a metal having a high Schottky barrier height. The third metal layer 53 may include a material identical to the first metal layer 51. For example, the third metal layer 53 may include nickel (Ni), gold (Au), or platinum (Pt). The third metal layer 53 partially forms a high barrier height on the boundary between the active region 21 and the junction termination layer 70 to prevent a leakage current caused by an electric field concentrated on the boundary between the active region 21 and the junction termination layer 70.

According to another embodiment, the conductive layers 70 and the junction termination layer 30 respectively include regions doped in different concentrations. Referring to FIGS. 2C and 2D, the conductive layers 70 may have a first part 71 and a second part 72 disposed on the first part 71. At this point, a dopant concentration of the second part 72 may be higher than that of the first part 71. For example, a concentration of impurity doped to the first part 71 may be 1-10¹⁵ cm^{—3} to 1-10¹⁸ cm⁻³. For example, a concentration of impurity doped to the second part 72 may be 1-10¹⁸ cm⁻³ to 5-10¹⁹ cm⁻³. The first part 71 may contact the active region 21 of the drift layer 20 to form a p-n junction. The second part 72 may contact the second metal layer 52 or the third metal layer 53 to form an ohmic junction. Through the ohmic junction of the second part 72, contact characteristics may be enhanced between the conductive layer 70 and the second metal layer 52 or the third metal layer 53.

Alternatively, as illustrated in FIGS. 2C and 2D, the junction termination layer 30 may include a third part 31 and a fourth part 32 disposed on the third part 31. At this point, a dopant concentration of the fourth part 32 may be higher than that of the third part 31. For example, a concentration of impurity doped to the third part 31 may be 1-10¹⁵ cm⁻³ to 1-10¹⁸ cm⁻³. For example, a concentration of impurity doped to the fourth part 32 may be 1-10¹⁸ cm⁻³ to 5-10¹⁹ cm⁻³. The third part 31 may contact the active region 21 of the drift layer 20 to form a p-n junction.

In a Schottky diode, when a reverse bias is applied to the element, an electric field may be concentrated on one end of a Schottky junction formed by the second metal layer and the drift layer. At this point, carriers may pass the Schottky barrier height due to the concentrated electric field, or a leakage current may be generated by tunneling.

In a Schottky diode according to embodiments of the inventive concept, a first metal layer having a higher Schottky barrier height than a second metal layer is disposed at one end of a Schottky junction formed by the second metal layer and the drift layer. Accordingly, the barrier height of the one end of the Schottky junction increases, and when a reverse bias is applied, generation of a leakage current by an electric field, which is concentrated on the one end of the Schottky junction, may be remarkably reduced. In addition, when a forward bias is applied, a current flows through a junction formed by the second metal layer having a low Schottky barrier height and the drift layer. In other words, a Schottky diode according to the inventive concept forms a partially high barrier height to improve a reverse blocking characteristic of the element without hindering forward current characteristics.

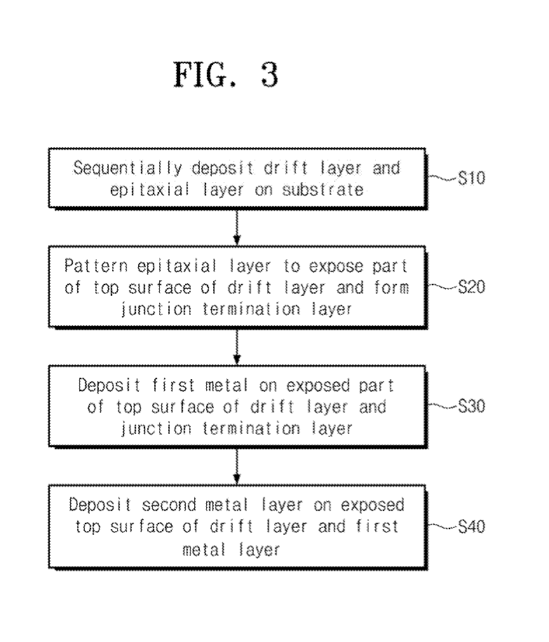

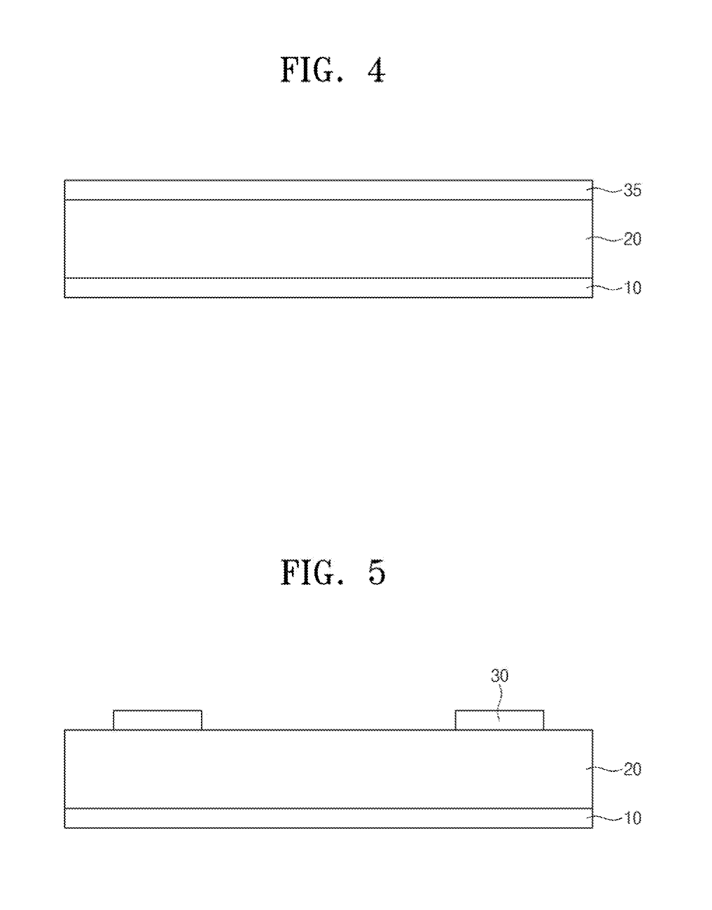

Hereinafter, a method for manufacturing a Schottky diode according to embodiments of the inventive concept will be described. FIG. 3 is a method for manufacturing a Schottky diode according to an embodiment of the inventive concept. FIGS. 4 to 9 are cross-sectional views for explaining the method of manufacturing a Schottky diode according to embodiments of the inventive concept.

Referring to FIGS. 3 and 4, a drift layer 20 and an epitaxial layer 35 may be sequentially deposited (step S10). For example, deposition of the drift layer 20 and the epitaxial layer 35 may be performed through continuous epitaxial growth processes. The substrate 10, the drift layer 20 and the epitaxial layer 35 may be semiconductor materials including silicon carbide (SiC). The substrate 10 may have an n+ conductive type. For example, the substrate 10 may be doped with n-type impurity (e.g. nitrogen (N) or phosphorous (P)) in a concentration of 1-10¹⁹ cm⁻³. The drift layer 20 may have an n-conductive type. For example, the drift layer 20 may be doped with n-type impurity (e.g. nitrogen (N) or phosphorous (P)) in a concentration of 1-10¹³ cm⁻³ to 1-10¹⁷ cm⁻³. The epitaxial layer 35 may have a p conductive type. For example, the epitaxial layer 35 may be doped with p-type impurity (e.g. aluminum (Al) or boron (B)) in a concentration of 1-10¹⁵ cm⁻³ to 1-10¹⁹ cm⁻³.

Referring to FIGS. 3 and 5, the epitaxial layer 35 may be patterned (step S20). The epitaxial layer 35 may be penetrated to be etched, and through this, the top surface of the drift layer 20 may be exposed. In detail, the epitaxial layer 35 may be etched such that the central part and edge part of the top surface of the drift layer 20 are exposed. The epitaxial layer 35, for which the etching process is undergone, may be the junction termination layer 30. According to another embodiment, although not illustrated in the drawing, the epitaxial layer 35 may be etched to form the junction termination layer 30 and the conductive layer 70 (in FIG. 2A). In other words, the conductive layer 70 may be formed simultaneously with the junction termination layer 30 and include the same material.

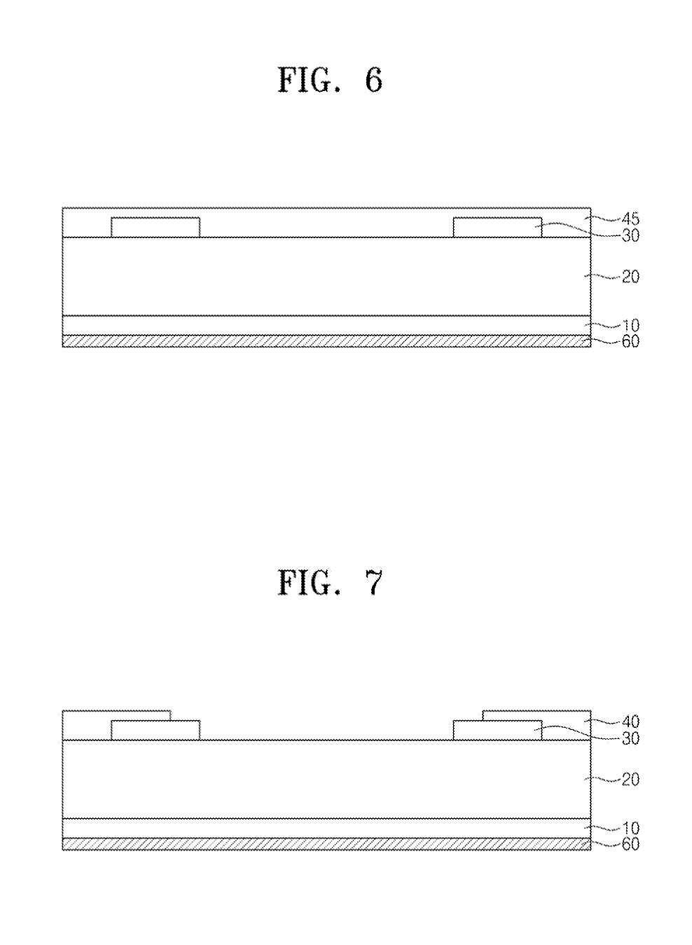

Referring to FIGS. 6 and 7, the dielectric layer 40 may be formed on the drift layer 20 and the junction termination layer 30. In detail, a dielectric material 45 may be coated on the drift layer 20 and the junction termination layer 30 and patterned to form the dielectric layer 40. For example, the patterning of the dielectric material 45 may be performed through a photolithography process. The central part of the drift layer 20 and a part of the junction termination layer 30 may be exposed by the patterning of the dielectric material 45. At this point, the exposed central part of the drift layer 20 may be defined as an active region of the element. The dielectric layer 45 may include silicon oxide (SiO2). An ohmic contact layer 60 may be deposited on one surface of the substrate 10 facing to the drift layer 20.

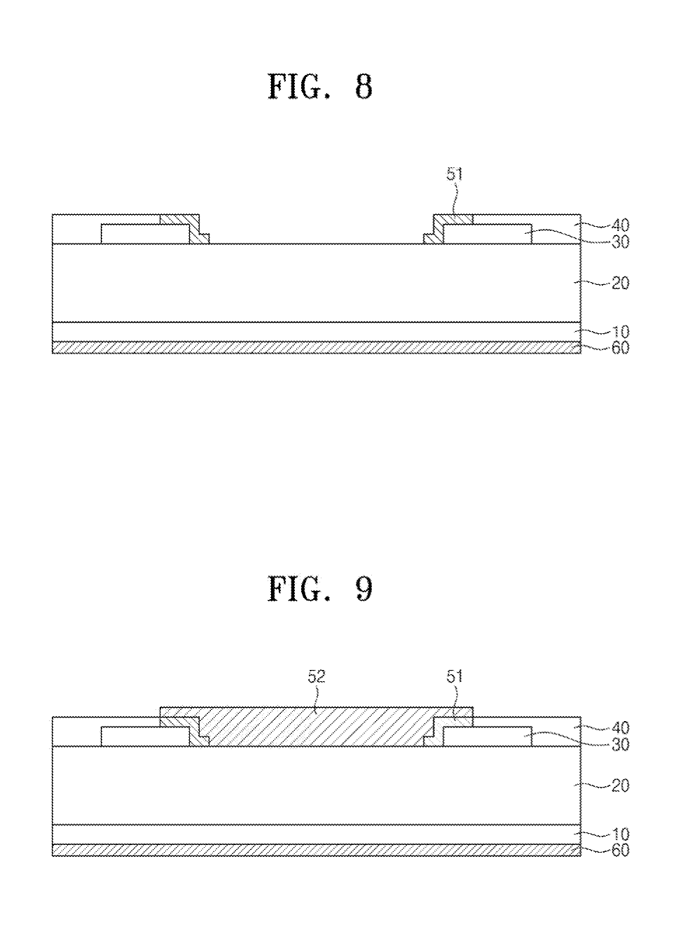

Referring to FIGS. 3 and 8, the first metal layer 51 may be deposited on the exposed part of the top surface of the drift layer 20 and the junction termination layer 30 (step S30). In detail, a first metal may be deposited on the exposed top surface of the drift layer 20 and the junction termination layer 30. The deposited first metal may be a metal having a large Schottky barrier height. For example, the first metal layer may include nickel (Ni), gold (Au), or platinum (Pt). Thereafter, the deposited first metal may be patterned to expose a part of the top surface of the drift layer 20. At this point, the patterning of the deposited first metal may be performed through photolithography and etching processes or through a metal lift-off process.

Referring to FIGS. 3 and 9, the second metal layer 52 may be deposited on the exposed top surface of the drift layer 20 and the first metal layer 51 (step S40). In detail, a second metal may be deposited on the exposed top surface of the drift layer 20 and the first metal layer 51 and then the deposited second metal may be patterned. At this point, the patterning of the deposited second metal may be performed through the photolithography and etching processes or through a metal lift-off process. The second metal may be a metal having lower Schottky barrier height than the first metal. For example, the second metal layer 52 may include titanium (Ti), aluminum (Al), niobium (Nb) or tantalum (Ta).

A Schottky diode according to embodiments of the inventive concept may be formed by accumulating semiconductor materials through continuous epitaxial growth processes. In addition, in order to enhance reverse blocking characteristics between the junction termination layer and the Schottky junction, a doping region by a high temperature injection process is not used. Accordingly, a method for manufacturing a Schottky diode according to embodiments of the inventive concept may minimize an impact of ion injection and an interface defect of an element, since a high temperature ion injection process and a high temperature heat treatment process for activating ion-injected dopants are not necessary.

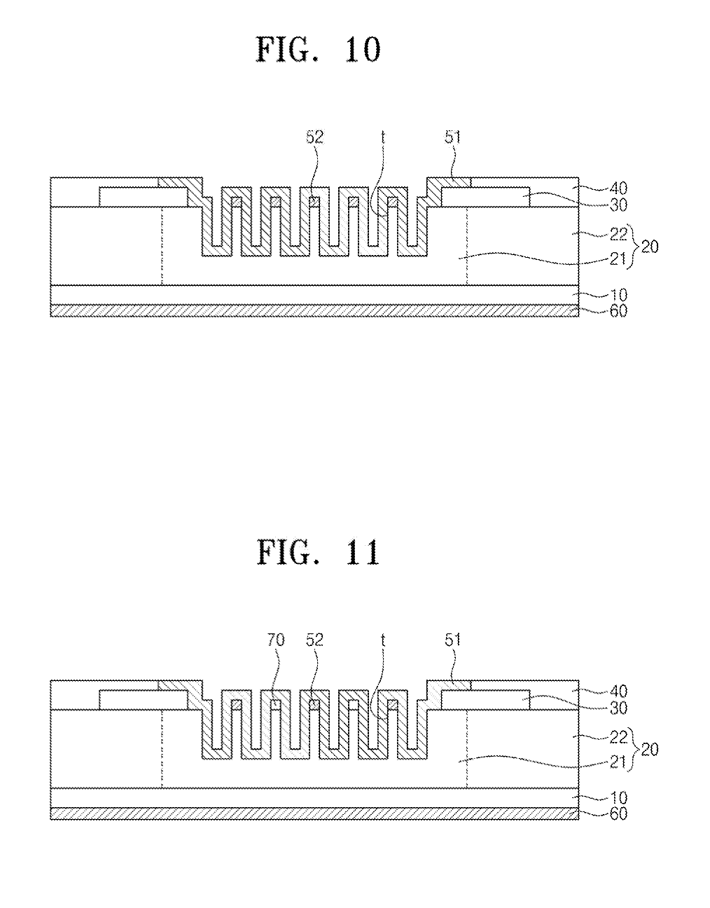

According to another embodiment, a Schottky diode may also include trenches in the active region of the drift layer and a plurality of conductive layers spaced apart from each other between the trenches. In other words, the Schottky diode may be a trench Schottky barrier diode (TSBD). FIGS. 10 to 12 are cross-sectional views for explaining a Schottky diode according to other embodiments of the inventive concept. For convenience of explanation, points different from the embodiment of FIG. 1 will be mainly described and omitted parts may also conform to an embodiment of the inventive concept.

Referring to FIG. 10, a substrate may be provided. The substrate 10 may include silicon carbide (SiC). The substrate 10 may be doped with impurities to have an n-type conductive type.

A drift layer 20 may be disposed on the substrate 10. The drift layer 20 may include silicon carbide (SiC). The drift layer 20 may be doped with impurities to have an n-type conductive type. For example, the drift layer 20 may be doped with nitrogen (N) or phosphorous (P). The dopant concentration of the drift layer 20 may be lower than that of the substrate. The drift layer 20 may include the active region 21 of the central part and the periphery 22 extending from the active region 21 in a lateral direction to surround the active region 21. The active region 21 may include trenches t thereon. The trenches t may be formed from the top surface of the active region 21 toward the substrate 10. The trenches t may be spaced apart from each other and the separation distance therebetween may be constant. A lateral side of the trench t may have a slope of about 50 to about 90 degrees with respect to the top surface of the drift layer 20.

The junction termination layer 30 may be disposed on the drift layer 20. In detail, the junction termination layer 30 may be disposed on a boundary between the active region 21 and the periphery 22. At this point, the junction termination layer 30 may cover only a part of the active region 21 and accordingly a part of the top surface of the active region may be exposed. In addition, the junction termination layer 30 may cover a part of or the entirety of the periphery 22. The junction termination layer 30 may include silicon carbide (SiC). The junction termination layer 30 may be doped with impurities to have a p-type conductive type. For example, aluminum (Al) or boron (B) may be doped to the junction termination layer 30. The junction termination layer 30 may play a role for reducing an electric field concentrated on a termination end of the active region 21. For example, the junction termination layer 30 may be a junction terminal extension or floating guard ring (FGR).

A dielectric layer 40 may be disposed on the junction termination layer 30 and the periphery 22. In detail, the dielectric layer 40 may cover a part of the junction termination layer 30 and the periphery 22. The dielectric layer 40 may include silicon oxide (SiO2).

The second metal layer 52 may be disposed on the active region 21. In detail, the second metal layer 52 may cover the top surface of the active region 21 but not be disposed in the trenches t. The second metal layer 52 may contact the active region 21 of the drift layer 20 to form a Schottky junction. The second metal layer 52 may include a metal having a low Schottky barrier height. For example, the second metal layer 52 may include titanium (Ti), aluminum (Al), niobium (Nb) or tantalum (Ta). The second metal layer 52 may be provided in plurality or only one.

The first metal layer 51 may be disposed on the active region 21, the second metal layer 52, and the junction termination layer 30. In detail, the first metal layer 51 may cover a part of the junction termination layer 30, the top surface of the active region 21, the surfaces of the trenches t of the active region 21, side surfaces and top surfaces of the conductive layers 70 of the active region 21, and the second metal layer 52. In other words, the first metal layer 51 may be coated along surface morphologies of the junction termination layer 30, the active region 21, and the second metal layer 52. The first metal layer 51 may contact the active region 21 of the drift layer 20 to form a Schottky junction. The first metal layer 51 may include a metal having a high Schottky barrier height. For example, the first metal layer 51 may include nickel (Ni), gold (Au), or platinum (Pt). The first metal layer 51 partially forms high barrier heights on the boundary between the active region 21 and the junction termination layer 30, and at a termination end of a junction formed by the active region 21 and the second metal 52 to prevent a leakage.

An ohmic contact layer 60 may be disposed on one surface of the substrate 10 facing the drift layer 20. The ohmic contact layer 60 may contact the substrate 10 to form an ohmic junction and play a role of a cathode of the element.

According to another embodiment, the conductive layers 70 may be disposed on the active region 21. In detail, the conductive layers 70 may cover the top surface of the active region 21 but not be disposed in the trenches t. The conductive layers 70 may have insular shapes. For example, the conductive layers 70 may be disposed on the active region 21 to be planarly spaced apart from each other. At this point, positions at which the conductive layers 70 are disposed may be between the second metal layers 52. In other words, the conductive layers 70 and the second metal layers 52 may be planarly and alternatively disposed. The conductive layer 70 may include the same material as that of the junction termination layer 30. For example, the conductive layers 70 may include silicon carbide (SiC). The conductive layers 70 may have conductive types different from that of the drift layer 20. The conductive layers 70 may contact the active region 21 of the drift layer 20 to form p-n junctions. The p-n junction may have a low voltage characteristic at a high current in comparison to the Schottky junction. Accordingly, when a surge current flows through the element, the p-n junction may lower an electric field applied to the element to protect the element.

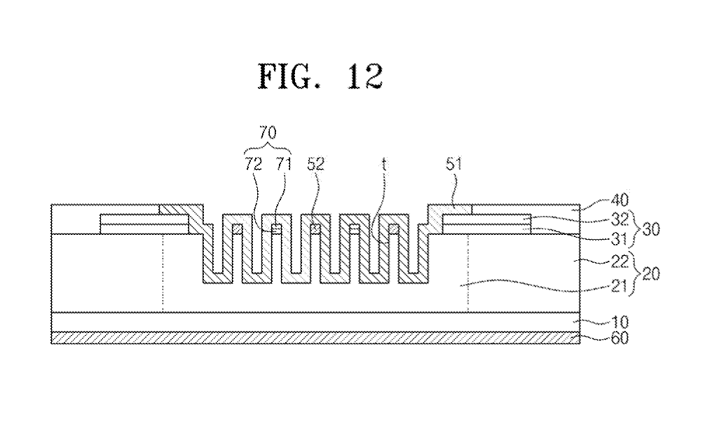

According to another embodiment, the conductive layers 70 and the junction termination layer 30 respectively include regions doped in different concentrations. Referring to FIG. 11, the conductive layers 70 may have a first part 71 and a second part 72 disposed on the first part 71. At this point, a dopant concentration of the second part 72 may be higher than that of the first part 71. The first part 71 may contact the active region 21 of the drift layer 20 to form a p-n junction. The second part 72 may contact the second metal layer 52 or the third metal layer 53 to form an ohmic junction. Through the ohmic junction of the second part 72, contact characteristics may be enhanced between the conductive layer 70 and the second metal layer 52 or the third metal layer 53.

Alternatively, as illustrated in FIG. 12, the junction termination layer 30 may include a third part 31 and a fourth part 32 disposed on the third part 31. At this point, a dopant concentration of the fourth part 32 may be higher than that of the third part 31. The third part 31 may contact the active region 21 of the drift layer 20 to form a p-n junction.

In a Schottky diode according to embodiments of the inventive concept, a first metal layer having a higher Schottky barrier height than a second metal layer is disposed at one end of a Schottky junction between the second metal layer and a drift layer. Accordingly, the barrier height of the one end of the Schottky junction increases, and when a reverse bias is applied, generation of a leakage current by an electric field, which is concentrated on the one end of the Schottky junction, may be remarkably reduced. In addition, when a forward bias is applied, a current flows through a junction formed by the second metal layer having a low Schottky barrier height and a drift layer. In other words, a Schottky diode according to the inventive concept has a partially high barrier height to improve a reverse blocking characteristic thereof without hindering forward current characteristics.

In addition, a method for manufacturing a Schottky diode according to embodiments of the inventive concept may minimize an impact of ion injection and an interface defect of the element, since a high temperature ion injection process and a high temperature heat treatment process for activating ion-injected dopants are not necessary.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A Schottky diode comprising:
a substrate;
a drift layer on the substrate, the drift layer comprising an active region and a periphery positioned at an edge of the active region;
a junction termination layer on a boundary between the active region and the periphery;
a first metal layer configured to cover a part of the active region and a part of the junction termination layer; and
a second metal layer configured to cover the first metal layer and the active region,
wherein the first metal layer and the second metal layer contact the drift layer to provide a Schottky junction, and
the first metal layer has a higher Schottky barrier height than the second metal layer.

2. The Schottky diode of claim 1, wherein the substrate, the drift layer and the junction termination layer comprise silicon carbide SiC.

3. The Schottky diode of claim 1, further comprising:
a plurality of conductive layers spaced apart from each other on the active region,
wherein the second metal layer covers the first metal layer, the active region, and the conductive layers.

4. The Schottky diode of claim 3, wherein the conductive layers have a conductive type different from that of the drift layer.

5. The Schottky diode of claim 3, wherein the conductive layers comprise a first part and a second part on the first part, and
the second part has a higher dopant concentration than the first part.

6. The Schottky diode of claim 3, further comprising:
a third metal layer configured to cover the conductive layers and a part of the active region,
wherein the second metal layer covers the first metal layer, the active region, and the third metal layer.

7. The Schottky diode of claim 6, wherein the third metal layer comprises a same material as that of the first metal layer.

8. The Schottky diode of claim 1, wherein the junction termination layer has a conductive type different from that of the drift layer.

9. The Schottky diode of claim 8, wherein the junction termination layer comprises a first junction termination layer and a second junction termination layer on the first junction termination layer, and
the second junction termination layer has a higher dopant concentration than the first junction termination layer.

10. A Schottky diode comprising:
a substrate;
a drift layer on the substrate, the drift layer comprising an active region comprising trenches extending in a substrate direction and a periphery positioned at an edge of the active region;
a junction termination layer on a boundary between the active region and the periphery;
a first metal layer configured to cover a part of the active region and a part of the junction termination layer; and
a plurality of second metal layers disposed separately from each other and configured to contact a top surface of the drift layer and the first metal layer,
wherein the first metal layer and the second metal layer contact the drift layer to provide a Schottky junction, and
the first metal layer has a higher Schottky barrier height than the second metal layer.

11. The Schottky diode of claim 10, wherein the first metal layer is coated along surface morphologies of the junction termination layer, the active region, and the second metal layer.

12. The Schottky diode of claim 10, further comprising:
conductive layers configured to contact a top surface of the drift layer and the first metal layer,
wherein the conductive layers are disposed between the second metal layers.

13. The Schottky diode of claim 10, wherein side walls of the trenches has slopes of about 50 to about 90 degrees with respect to bottom surfaces of the trenches.

14. The Schottky diode of claim 13, wherein the conductive layers have a conductive type different from that of the drift layer.

15. The Schottky diode of claim 14, wherein the conductive layers comprise a first part and a second part on the first part, and
the second part has a higher dopant concentration than the first part.
